(19) United States
(12) Patent Application Publication
(10) Pub. No.: US 2024/0016072 A1
(43) Pub. Date: Jan. 11, 2024

(54) MEMORY CELL, INTEGRATED CIRCUIT, AND MANUFACTURING METHOD OF MEMORY CELL

(71) Applicant: Taiwan Semiconductor Manufacturing Company, Ltd., Hsinchu (TW)

(72) Inventors: Hengyuan Lee, Hsinchu County (TW); Yu-Sheng Chen, Taoyuan City (TW); Cheng-Chun Chang, Taoyuan City (TW); Xinyu BAO, Fremont, CA (US)

(73) Assignee: Taiwan Semiconductor Manufacturing Company, Ltd., Hsinchu (TW)

(21) Appl. No.: 17/859,013

(22) Filed: Jul. 7, 2022

(51) Int. Cl. H01L 45/00; H01L 27/24

(52) U.S. Cl. CPC H01L 45/126; H01L 27/2436; H01L 45/06; H01L 45/144; H01L 45/1675

(57) ABSTRACT

A memory cell includes a bottom electrode, a thermal preservation layer, a first dielectric layer, a variable resistance layer, and a top electrode. The bottom electrode includes a first electrode and a second electrode spatially separated from the first electrode. The thermal preservation layer is partially sandwiched between the first electrode and the second electrode. The first dielectric layer laterally surrounds the bottom electrode and the thermal preservation layer. The variable resistance layer is disposed on the second electrode, the thermal preservation layer, and the first dielectric layer. The top electrode is disposed on the variable resistance layer.

### BACKGROUND

Flash memory is a widely used type of nonvolatile memory. However, flash memory is expected to encounter scaling difficulties. Therefore, alternatives types of nonvolatile memory are being explored. Among these alternatives types of nonvolatile memory is phase change memory (PCM). PCM is a type of nonvolatile memory in which a phase of a PCM is employed to represent a unit of data. PCM has fast read and write times, non-destructive reads, and high scalability.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross-sectional view of an integrated circuit in accordance with some embodiments of the disclosure.

FIG. 2A to FIG. 2Q are schematic cross-sectional views illustrating various stages of a manufacturing method of the memory cell in FIG. 1.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

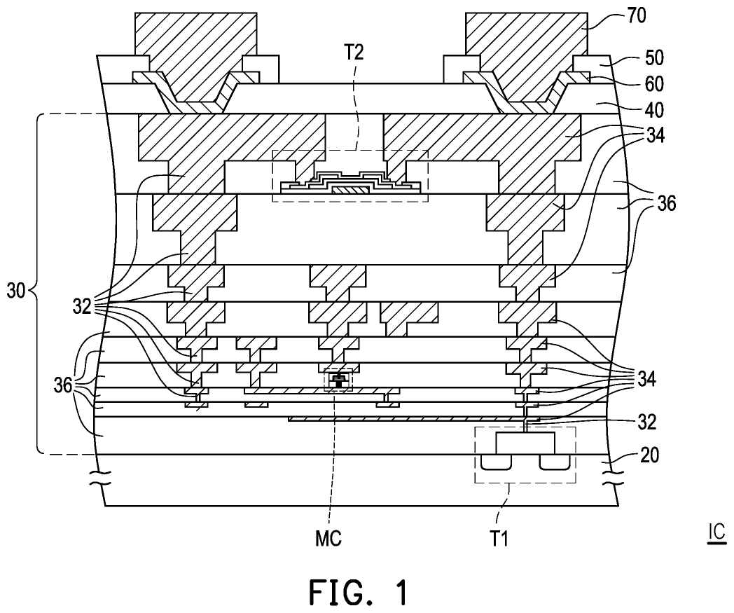

FIG. 1 is a schematic cross-sectional view of an integrated circuit IC in accordance with some embodiments of the disclosure. In some embodiments, the integrated circuit IC includes a substrate 20, an interconnect structure 30, a passivation layer 40, a post-passivation layer 50, a plurality of conductive pads 60, a plurality of conductive terminals 70, and a first transistor T1. In some embodiments, the substrate 20 is made of elemental semiconductor materials, such as crystalline silicon, diamond, or germanium; compound semiconductor materials, such as silicon carbide, gallium arsenic, indium arsenide, or indium phosphide; or alloy semiconductor materials, such as silicon germanium, silicon germanium carbide, gallium arsenic phosphide, or gallium indium phosphide. The substrate 20 may be a bulk silicon substrate, a silicon-on-insulator (SOI) substrate, or a germanium-on-insulator (GOI) substrate.

In some embodiments, the substrate 20 includes various doped regions depending on circuit requirements (e.g., p-type semiconductor substrate or n-type semiconductor substrate). In some embodiments, the doped regions are doped with p-type or n-type dopants. For example, the doped regions may be doped with p-type dopants, such as boron or BF₂; n-type dopants, such as phosphorus or arsenic; and/or combinations thereof. In some embodiments, these doped regions serve as source/drain regions of the first transistor T1, which is over the substrate 20. Depending on the types of the dopants in the doped regions, the first transistor T1 may be referred to as n-type transistor or p-type transistor. In some embodiments, the first transistor T1 further includes a metal gate and a channel under the metal gate. The channel is located between the source region and the drain region to serve as a path for electron to travel when the first transistor T1 is turned on. On the other hand, the metal gate is located above the substrate 20 and is embedded in the interconnect structure 30. In some embodiments, the first transistor T1 is formed using suitable Front-end-of-line (FEOL) process. For simplicity, one first transistor T1 is shown in FIG. 1. However, it should be understood that more than one first transistors T1 may be presented depending on the application of the integrated circuit IC. When multiple first transistors T1 are presented, these first transistors T1 may be separated by shallow trench isolation (STI; not shown) located between two adjacent first transistors T1.

As illustrated in FIG. 1, the interconnect structure 30 is disposed on the substrate 20. In some embodiments, the interconnect structure 30 includes a plurality of conductive vias 32, a plurality of conductive patterns 34, a plurality of dielectric layers 36, a memory cell MC, and a second transistor T2. As illustrated in FIG. 1, the conductive patterns 34 and the conductive vias 32 are embedded in the dielectric layers 36. In some embodiments, the conductive patterns 34 located at different level heights are connected to one another through the conductive vias 32. In other words, the conductive patterns 34 are electrically connected to one another through the conductive vias 32. In some embodiments, the bottommost conductive vias 32 are connected to the first transistor T1. For example, the bottommost conductive vias 32 are connected to the metal gate, which is embedded in the bottommost dielectric layer 36, of the first transistor T1. In other words, the bottommost conductive vias 32 establish electrical connection between the first transistor T1 and the conductive patterns 34 of the interconnect structure 30. As illustrated in FIG. 1, the bottommost conductive via 32 is connected to the metal gate of the first transistor T1. However, it should be noted that in some alternative cross-sectional views, other bottommost conductive vias 32 are also connected to source/drain regions of the first transistor T1. That is, in some embodiments, the bottommost conductive vias 32 may be referred to as “contact structures” of the first transistor T1.

In some embodiments, a material of the dielectric layers 36 includes polyimide, epoxy resin, acrylic resin, phenol resin, benzocyclobutene (BCB), polybenzooxazole (PBO), or any other suitable polymer-based dielectric material. Alternatively, the dielectric layers 36 may be formed of oxides or nitrides, such as silicon oxide, silicon nitride, or the like. The dielectric layers 36 may be formed by suitable fabrication techniques such as spin-on coating, chemical vapor deposition (CVD), plasma-enhanced chemical vapor deposition (PECVD), or the like.

In some embodiments, a material of the conductive patterns 34 and the conductive vias 32 includes aluminum, titanium, copper, nickel, tungsten, or alloys thereof. The conductive patterns 34 and the conductive vias 32 may be formed by electroplating, deposition, and/or photolithography and etching. In some embodiments, the conductive patterns 34 and the underlying conductive vias 32 are formed simultaneously. It should be noted that the number of the dielectric layers 36, the number of the conductive patterns 34, and the number of the conductive vias 32 illustrated in FIG. 1 are merely for illustrative purposes, and the disclosure is not limited thereto. In some alternative embodiments, fewer or more layers of the dielectric layers 36, the conductive patterns 34, and/or the conductive vias 32 may be formed depending on the circuit design.

As illustrated in FIG. 1, the memory cell MC is embedded in the interconnection structure 30. For example, the memory cell MC is embedded in one of the dielectric layers 36. For simplicity, one memory cell MC is shown in FIG. 1. However, it should be understood that more than one memory cells MC may be presented depending on the application of the integrated circuit IC. The formation method and the structure of the memory cell MC will be described in detail later.

In some embodiments, the second transistor T2 is also embedded in the interconnection structure 30. For example, the second transistor T2 is embedded in one of the dielectric layers 36. For simplicity, one second transistor T2 is shown in FIG. 1. However, it should be understood that more than one second transistors T2 may be presented depending on the application of the integrated circuit IC. In some embodiments, the second transistor T2 is electrically connected to the conductive patterns 34 through the corresponding conductive vias 32. In some embodiments, the second transistor T2 is a thin-film transistors (TFT). For example, the second transistor T2 includes a gate electrode, a gate dielectric layer, a channel layer, and source/drain regions. The gate dielectric layer is sandwiched between the channel layer and the gate electrode. The source/drain regions are respectively disposed at two opposite ends of the channel layer. As illustrated in FIG. 1, the conductive vias 32 are in physical contact with the source/drain regions to render electrical connection with the second transistor T2. It should be noted that in some alternative cross-sectional views, another conductive via 32 is also connected to the gate electrode of the second transistor T2. In some embodiments, the second transistor T2 is electrically connected to the memory cell MC. In some embodiments, the second transistor T2 and the memory cell MC may be collectively referred to as a memory device. For example, the second transistor T2 may serve as a selector for the memory device. As will be described later, since the memory cell MC includes phase change materials, the memory device illustrated in FIG. 1 may be referred to as Phase Change Random Access Memory (PCRAM) device. In some embodiments, since the second transistor T2 and the memory cell MC are embedded in the interconnection structure 30, the second transistor T2 and the memory cell MC are being considered as formed during back-end-of-line (BEOL) process. It should be noted that although FIG. 1 illustrated the second transistor T2 and the memory cell MC as being embedded in different dielectric layers 36, the disclosure is not limited thereto. In some alternative embodiments, the second transistor T2 and the memory cell MC are embedded in the same dielectric layer 36.

As illustrated in FIG. 1, the passivation layer 40, the conductive pads 60, the post-passivation layer 50, and the conductive terminals 70 are sequentially formed on the interconnect structure 30. In some embodiments, the passivation layer 40 is disposed on the topmost dielectric layer 36 and the topmost conductive patterns 34. In some embodiments, the passivation layer 40 has a plurality of openings partially exposing each topmost conductive pattern 34. In some embodiments, the passivation layer 40 is a silicon oxide layer, a silicon nitride layer, a silicon oxy-nitride layer, or a dielectric layer formed by other suitable dielectric materials. The passivation layer 40 may be formed by suitable fabrication techniques such as high-density-plasma chemical vapor deposition (HDP-CVD), PECVD, or the like.

In some embodiments, the conductive pads 60 are formed over the passivation layer 40. In some embodiments, the conductive pads 60 extend into the openings of the passivation layer 40 to be in physical contact with the topmost conductive patterns 34. That is, the conductive pads 60 are electrically connected to the interconnect structure 30. In some embodiments, the conductive pads 60 include aluminum pads, copper pads, titanium pads, nickel pads, tungsten pads, or other suitable metal pads. The conductive pads 60 may be formed by, for example, electroplating, deposition, and/or photolithography and etching. It should be noted that the number and the shape of the conductive pads 60 illustrated in FIG. 1 are merely for illustrative purposes, and the disclosure is not limited thereto. In some alternative embodiments, the number and the shape of the conductive pads 60 may be adjusted based on demand.

In some embodiments, the post-passivation layer 50 is formed over the passivation layer 40 and the conductive pads 60. In some embodiments, the post-passivation layer 50 is formed on the conductive pads 60 to protect the conductive pads 60. In some embodiments, the post-passivation layer 50 has a plurality of contact openings partially exposing each conductive pad 60. The post-passivation layer 50 may be a polyimide layer, a PBO layer, or a dielectric layer formed by other suitable polymers. In some embodiments, the post-passivation layer 50 is formed by suitable fabrication techniques such as HDP-CVD, PECVD, or the like.

As illustrated in FIG. 1, the conductive terminals 70 are formed over the post-passivation layer 50 and the conductive pads 60. In some embodiments, the conductive terminals 70 extend into the contact openings of the post-passivation layer 50 to be in physical contact with the corresponding conductive pad 60. That is, the conductive terminals 70 are electrically connected to the interconnect structure 30 through the conductive pads 60. In some embodiments, the conductive terminals 70 are conductive pillars, conductive posts, conductive balls, conductive bumps, or the like. In some embodiments, a material of the conductive terminals 70 includes a variety of metals, metal alloys, or metals and mixture of other materials. For example, the conductive terminals 70 may be made of aluminum, titanium, copper, nickel, tungsten, tin, and/or alloys thereof. The conductive terminals 70 are formed by, for example, deposition, electroplating, screen printing, or other suitable methods. In some embodiments, the conductive terminals 70 are used to establish electrical connection with other components (not shown) subsequently formed or provided.

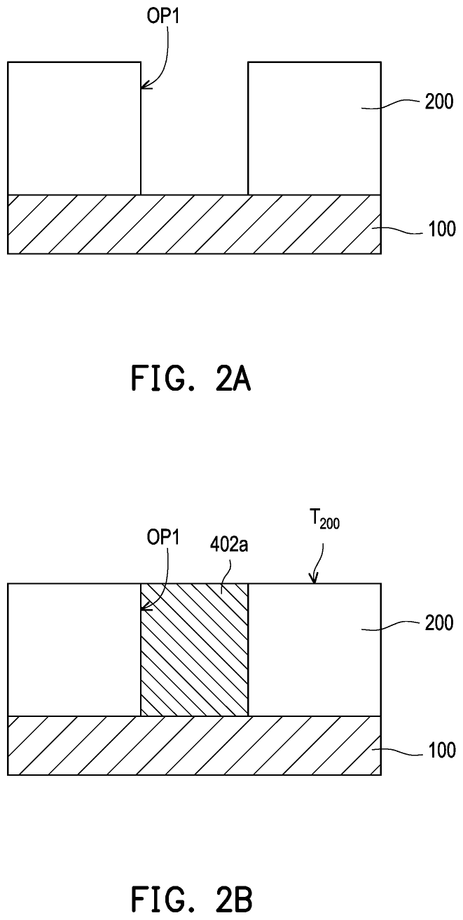

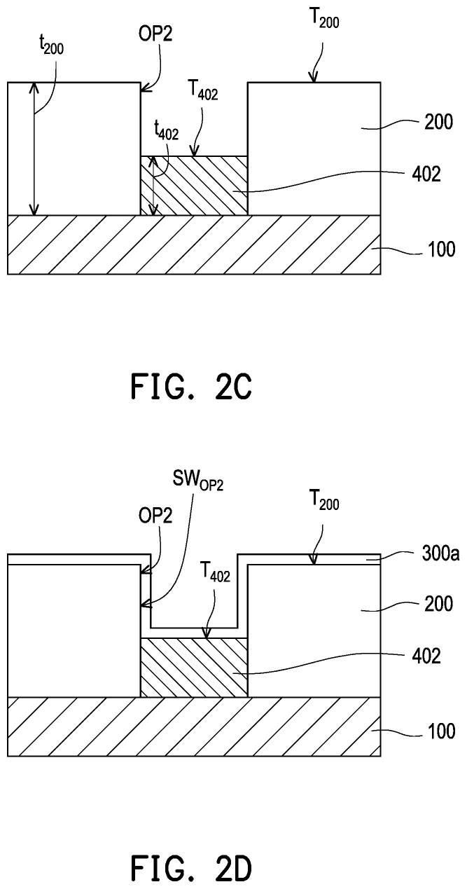

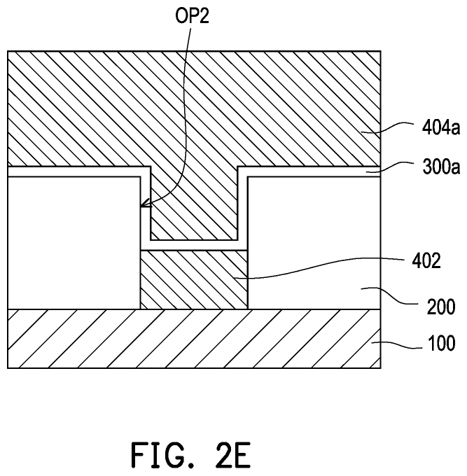

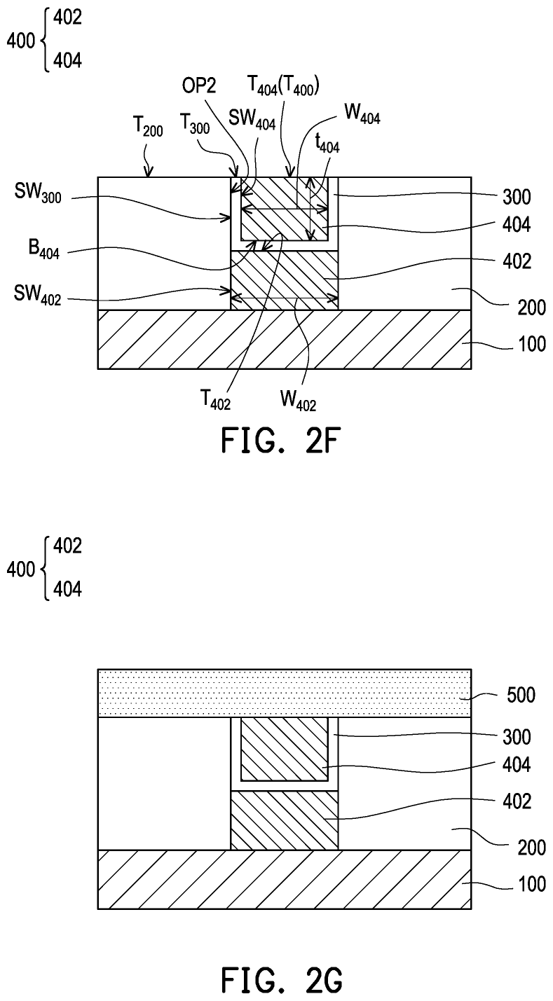

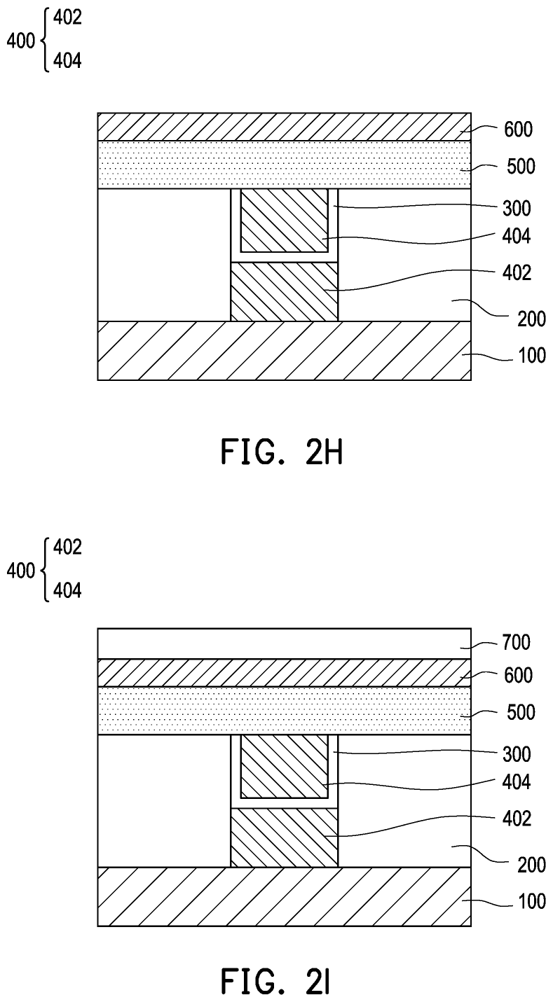

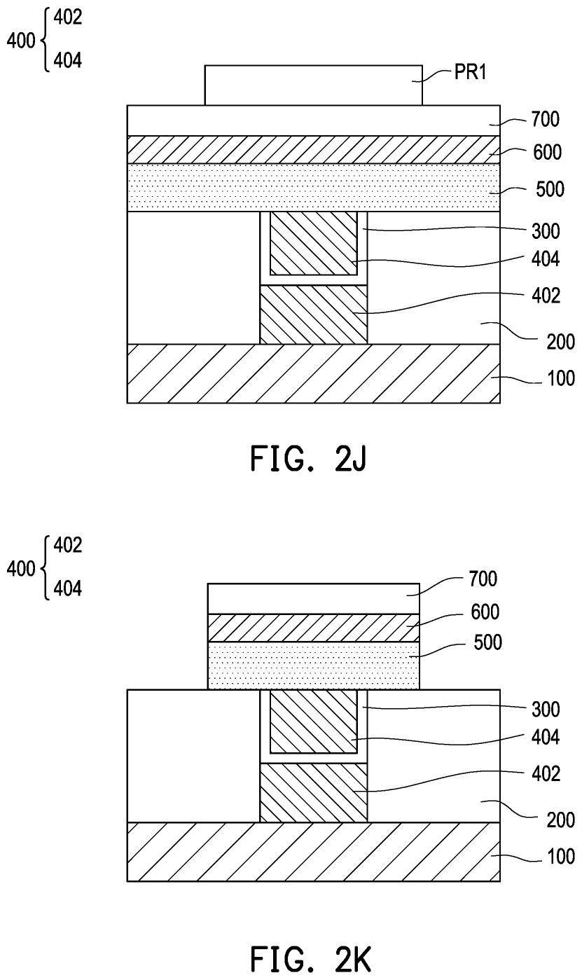

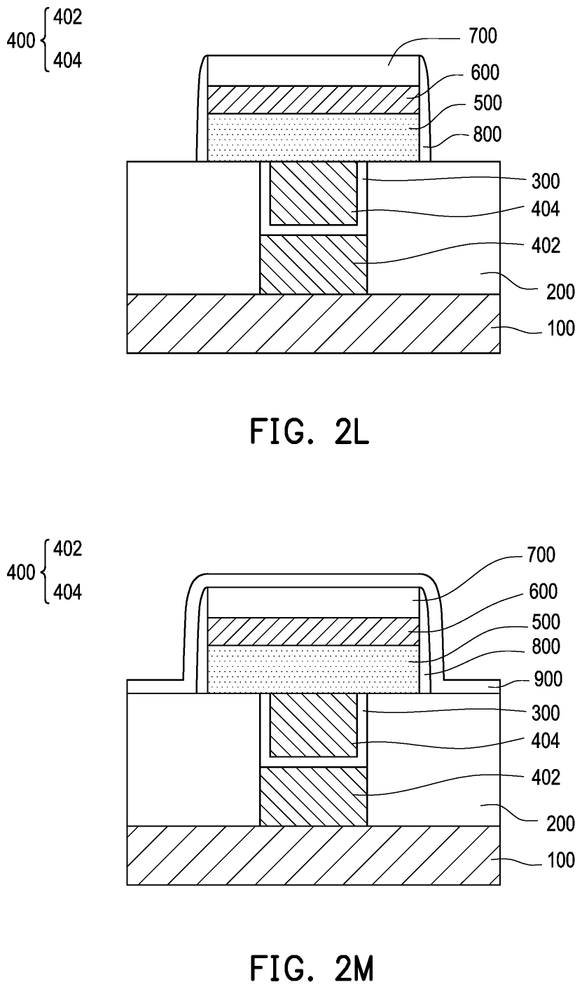

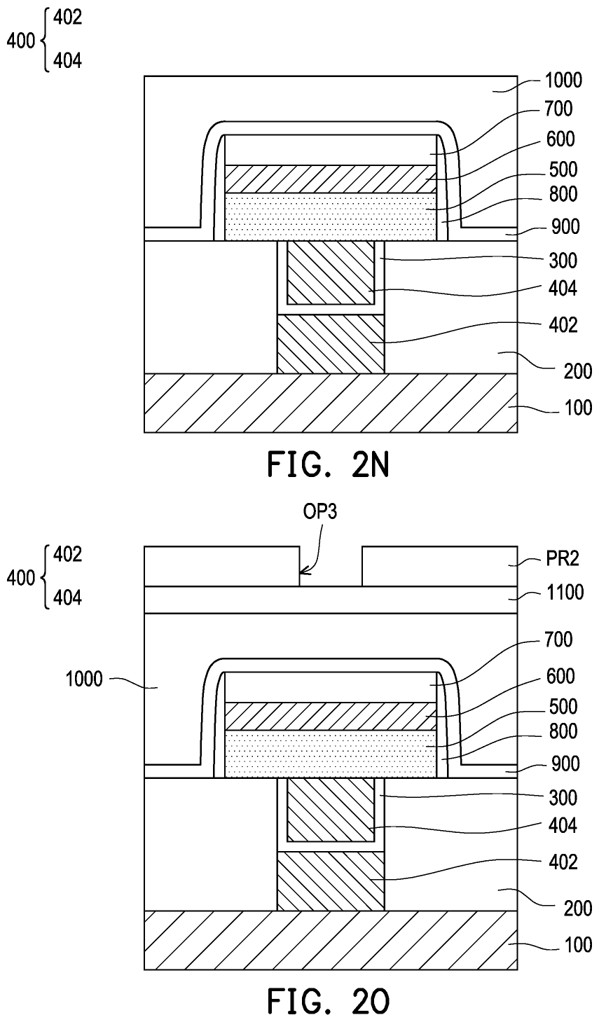

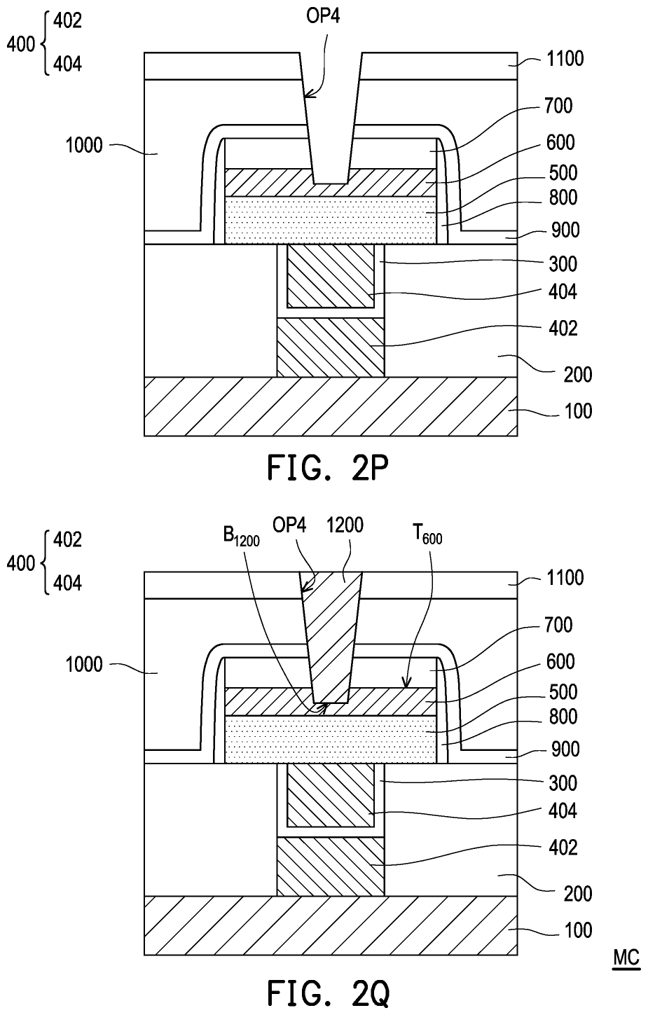

As mentioned above, the memory cell MC is embedded in the interconnection structure 30. The formation method and the structure of the memory cell MC will be described below in conjunction with FIG. 2A to FIG. 2Q.

FIG. 2A to FIG. 2Q are schematic cross-sectional views illustrating various stages of a manufacturing method of the memory cell MC in FIG. 1. Referring to FIG. 2A, a conductive layer 100 is provided. In some embodiments, the conductive layer 100 is one of the conductive patterns 34 of the interconnection structure 30 of FIG. 1, so the detailed description thereof is omitted herein. Thereafter, a dielectric layer 200 is formed on the conductive layer 100. In some embodiments, the dielectric layer 200 is formed of a low-k dielectric material having a dielectric constant (k-value) lower than about 3.0, about 2.5, or even lower. In some alternative embodiments, the dielectric layer 200 is formed of non-low-k dielectric materials such as silicon oxide, silicon carbide (SiC), silicon carbo-nitride (SiCN), silicon oxy-carbo-nitride (SiOCN), or the like. In yet some alternative embodiments, the material of the dielectric layer 200 includes polyimide, epoxy resin, acrylic resin, phenol resin, BCB, PBO, or any other suitable polymer-based dielectric material. The dielectric layer 200 may be formed by suitable fabrication techniques such as spin-on coating, CVD, PECVD, or the like.

In some embodiments, the dielectric layer 200 has an opening OP1. For example, the dielectric layer 200 is patterned to form the opening OP1. In some embodiments, the dielectric layer 200 is patterned through a photolithography and etching process. For example, a patterned photoresist layer (not shown) is formed on the dielectric layer 200. Thereafter, an etching process is performed to remove the dielectric layer 200 that is not covered by the patterned photoresist layer. The etching process includes, for example, an anisotropic etching process such as dry etch or an isotropic etching process such as wet etch. Subsequently, the patterned photoresist layer is removed through a stripping process or the like to expose the remaining dielectric layer 200. As illustrated in FIG. 2A, the opening OP1 penetrates through the dielectric layer 200 to expose the underlying conductive layer 100.

Referring to FIG. 2B, a first electrode material layer 402a is deposited in the opening OP1 of the dielectric layer 200. In some embodiments, the first electrode material layer 402a is formed to completely fill up the opening OP1. In some embodiments, the first electrode material layer 402a includes a metallic material, such as Ti, Co, Cu, AlCu, W, TiN, TiW, TiAl, TiAlN, Ru, a combination thereof, or the like. In some alternative embodiments, the first electrode material layer 402a includes a metal oxide material, such as TiOₓ, WOₓ, RuOₓ, a combination thereof, or the like. In some embodiments, the first electrode material layer 402a is deposited through atomic layer deposition (ALD), CVD, physical vapor deposition (PVD), or the like. In some embodiments, during the deposition of the first electrode material layer 402a, the first electrode material layer 402a may overflow from the opening OP1 to cover a top surface T₂₀₀ of the dielectric layer 200. Under this scenario, a grinding process, such as a mechanical grinding process, a chemical mechanical polishing (CMP) process, or the like, may be performed to remove excessive first electrode material layer 402a, so as to expose the top surface T₂₀₀ of the dielectric layer 200. As illustrated in FIG. 2B, the first electrode material layer 402a completely fills up the opening OP1. However, the disclosure is not limited thereto. In some alternative embodiments, the first electrode material layer 402a may partially fill up the opening OP1.

Referring to FIG. 2B and FIG. 2C, a portion of the first electrode material layer 402a is removed to form a first electrode 402 in the opening OP1 of the dielectric layer 200. In some embodiments, the portion of the first electrode material layer 402a is removed through an etching process. The etching process includes, for example, an anisotropic etching process such as dry etch or an isotropic etching process such as wet etch. In some embodiments, the first electrode 402 partially fills up the opening OP1. For example, the first electrode 402 is formed in the opening OP1 such that a top surface T₄₀₂ of the first electrode 402 is located at a level height lower than that of a top surface T₂₀₀ of the dielectric layer 200. In other words, a thickness t₄₀₂ of the first electrode 402 is smaller than a thickness t₂₀₀ of the dielectric layer 200. In some embodiments, the dielectric layer 200 and the first electrode 402 define an opening OP2.

Referring to FIG. 2D, a thermal preservation material layer 300a is conformally deposited on the dielectric layer 200 and the first electrode 402. For example, the thermal preservation material layer 300a covers the top surface T₂₀₀ of the dielectric layer 200 and extends into the opening OP2 to cover sidewalls SW_{OP2} of the opening OP2 and the top surface T₄₂₀ of the first electrode 420. In some embodiments, the thermal preservation material layer 300a exhibits a U-shape in the cross-sectional view, as illustrated in FIG. 2D. In some embodiments, the thermal preservation material layer 300a extends into the opening OP2 to be in physical contact with the first electrode 402. Meanwhile, the thermal preservation material layer 300a is spatially separated from the conductive layer 100 by the first electrode 402. In some embodiments, a material of the thermal preservation material layer 300a is different from the material of the first electrode 402. For example, the material of the thermal preservation material layer 300a includes titanium nitride (TiN), tantalum nitride (TaN), titanium silicon nitride (TiSiN), tantalum silicon nitride (TaSiN), tungsten silicon nitride (WSiN), titanium carbide (TiC), tantalum carbide (TaC), titanium aluminum carbide (TiAlC), tantalum aluminum carbide (TaAlC), titanium aluminum nitride (TiAlN), tantalum aluminum nitride (TaAlN), or a combination thereof. In some embodiments, the thermal preservation material layer 300a is formed by a suitable deposition process, such as CVD, PECVD, flowable chemical vapor deposition (FCVD), HDP-CVD, sub-atmospheric chemical vapor deposition (SACVD), PVD, or ALD.

Referring to FIG. 2E, a second electrode material layer 404a is formed on the thermal preservation material layer 300a. For example, the second electrode material layer 404a covers a top surface of the thermal preservation material layer 300a. In some embodiments, the second electrode material layer 404a completely fills up the opening OP2. In some embodiments, a material of the second electrode material layer 404a and the material of the first electrode 402 are the same. However, the disclosure is not limited thereto. In some alternative embodiments, the material of the second electrode material layer 404a is different from the material of the first electrode 402. For example, the second electrode material layer 404a includes a metallic material, such as Ti, Co, Cu, AlCu, W, TiN, TiW, TiAl, TiAlN, Ru, a combination thereof, or the like. In some alternative embodiments, the second electrode material layer 404a includes a metal oxide material, such as TiOₓ, WOₓ, RuOₓ, a combination thereof, or the like. In some embodiments, the second electrode material layer 404a is deposited through ALD, CVD, PVD, or the like. In some embodiments, the material of the second electrode material layer 404a is different from the material of the thermal preservation material layer 300a.

Referring to FIG. 2E and FIG. 2F, a portion of the thermal preservation material layer 300a and a portion of the second electrode material layer 404a are removed. For example, the thermal preservation material layer 300a and the second electrode material layer 404a shown in FIG. 2E are thinned until the underlying dielectric layer 200 is exposed, so as to form a thermal preservation layer 300 and a second electrode 404 in the opening OP2. In some embodiments, the thermal preservation material layer 300a and the second electrode material layer 404a are thinned through a grinding process, such as a mechanical grinding process, a CMP process, or the like.

As illustrated in FIG. 2F, the thermal preservation layer 300 and the second electrode 404 are sequentially formed on the first electrode 402 to completely fill up the opening OP2. In some embodiments, the first electrode 402 and the second electrode 404 are collectively referred to as a bottom electrode 400. That is, the bottom electrode 400 includes the first electrode 402 and the second electrode 402. In some embodiments, the top surface T₂₀₀ of the dielectric layer 200, a top surface T₃₀₀ of the thermal preservation layer 300, and a top surface T₄₀₀ of the bottom electrode 400 (i.e. a top surface T₄₀₄ of the second electrode 404) are substantially located at the same level height. In other words, the top surface T₂₀₀ of the dielectric layer 200, the top surface T₃₀₀ of the thermal preservation layer 300, and the top surface T₄₀₀ of the bottom electrode 400 are substantially coplanar.

Referring to FIG. 2A and FIG. 2F simultaneously, the opening OP1 in FIG. 2A is being completely filled up by the bottom electrode 400 (i.e. the first electrode 402 and the second electrode 404) and the thermal preservation layer 300. In other words, the thermal preservation layer 300 and the bottom electrode 400 (i.e. the first electrode 402 and the second electrode 404) are embedded in the dielectric layer 200. That is, the dielectric layer 200 laterally surrounds the thermal preservation layer 300 and the bottom electrode 400. As illustrated in FIG. 2F, the first electrode 402 is spatially separated from the second electrode 404. For example, the thermal preservation layer 300 is partially sandwiched between the first electrode 402 and the second electrode 404 to spatially separate the first electrode 402 from the second electrode 404. That is, the thermal preservation layer 300 covers the top surface T₄₀₂ of the first electrode 402. In some embodiments, the thermal preservation layer 300 is also partially sandwiched between the second electrode 404 and the dielectric layer 200. For example, the thermal preservation layer 300 covers a bottom surface B₄₀₄ and sidewalls SW₄₀₄ of the second electrode 404 to laterally surround the second electrode 404. In some embodiments, the thermal preservation layer 300 exhibits a U-shape from the cross-sectional view.

As illustrated in FIG. 2F, sidewalls SW₃₀₀ of the thermal preservation layer 300 are aligned with sidewalls SW₄₀₂ of the first electrode 402. Meanwhile, the sidewalls SW₃₀₀ of the thermal preservation layer 300 and the sidewalls SW₄₀₂ of the first electrode 402 are being covered by the dielectric layer 200. For example, the sidewalls SW₃₀₀ of the thermal preservation layer 300 and the sidewalls SW₄₀₂ of the first electrode 402 are in physical contact with the dielectric layer 200. On the other hand, the sidewalls SW₄₀₄ of the second electrode 404 are spatially separated from the dielectric layer 200 by the thermal preservation layer 300. In some embodiments, a width W₄₀₂ of the first electrode 402 is larger than a width W₄₀₄ of the second electrode 404. In some embodiments, a thickness t₄₀₄ of the second electrode 404 is greater than 0 nm and is less than 1 μm.

As mentioned above, the first electrode 402 and the second electrode 404 may be made of a same material. Meanwhile, the material of the thermal preservation layer 300 is different from the material of the first electrode 402 and the material of the second electrode 404. In other words, the bottom electrode 400 and the thermal preservation layer 300 are made of different materials. In some embodiments, the thermal preservation layer 300 is made of a material that has higher electrical resistance than that of the material of the bottom electrode 400. That is, an electrical resistance of the thermal preservation layer 300 is higher than an electrical resistance of the bottom electrode 400. As such, upon heating, a temperature of the thermal preservation layer 300 may be higher than a temperature of the bottom electrode 400. In certain embodiments, the first electrode 402 and the second electrode 404 are made of TiN while the thermal preservation layer 300 is made of TaN. However, the disclosure is not limited thereto. The first electrode 402, the thermal preservation layer 300, and the second electrode 404 may utilize the materials listed above as long as the material of the thermal preservation layer 300 renders higher electrical resistance than the materials of the first electrode 402 and the second electrode 404.

Referring to FIG. 2G, a variable resistance layer 500 is deposited on the dielectric layer 200, the thermal preservation layer 300, and the bottom electrode 400. For example, the variable resistance layer 500 is deposited on the dielectric layer 200, the thermal preservation layer 300, and the second electrode 404. In some embodiments, the variable resistance layer 500 includes a phase change material. The phase change material may include a chalcogenide material, such as an indium (In)-antimony(Sb)-tellurium (Te) (IST) material or a germanium(Ge)-antimony(Sb)-tellurium(Te) (GST) material. In some embodiments, the IST material includes In₂Sb₂Te₅, In₁Sb₂Te₄, In₁Sb₄Te₇, or the like. On the other hand, the GST material includes GesSb₅Te₈, Ge₂Sb₂Te₅, Ge₁Sb₂Te₄, Ge₁Sb₄Te₇, Ge₄Sb₄Te₇, Ge₄SbTe₂, Ge₆SbTe₂, or the like. The hyphenated chemical composition notation, as used herein, indicates the elements included in a particular mixture or compound, and is intended to represent all stoichiometries involving the indicated elements. In some alternative embodiments, other phase change materials may include Ge—Te, In—Se, Sb—Te, Ga—Sb, In—Sb, As—Te, Al—Te, Ge—Sb—Te, Te—Ge—As, In—Sb—Te, Te—Sn—Se, Ge—Se—Ga, Bi—Se—Sb, Ga—Se—Te, Sn—Sb—Te, In—Sb—Ge, Te—Ge—Sb—S, Te—Ge—Sn—O, Te—Ge—Sn—Au, Pd—Te—Ge—Sn, In—Se—Ti—Co, Ge—Sb—Te—Pd, Ge—Sb—Te—Co, Sb—Te—Bi—Se, Ag—In—Sb—Te, Ge—Sb—Se—Te, Ge—Sn—Sb—Te, Ge—Te—Sn—Ni, Ge—Te—Sn—Pd, and Ge—Te—Sn—Pt. In some embodiments, the variable resistance layer 500 is deposited by a suitable deposition process, such as CVD, PECVD, FCVD, HDP-CVD, SACVD, PVD, or ALD.

In some embodiments, since the variable resistance layer 500 includes a phase change material, the variable resistance layer 500 has a variable phase representing a data bit. For example, the variable resistance layer 500 has a crystalline phase and an amorphous phase which are interchangeable. The crystalline phase and the amorphous phase may respectively represent a binary “1” and a binary “0,” or vice versa. Accordingly, the variable resistance layer 500 has a variable resistance that changes with the variable phase of the variable resistance layer 500. For example, the variable resistance layer 500 has a high resistance in the amorphous phase and a low resistance in the crystalline phase.

In some embodiments, the phase of the variable resistance layer 500 is changed by heating. For example, the bottom electrode 400 heats the variable resistance layer 500 to a first temperature that induces crystallization of the variable resistance layer 500, so as to change the variable resistance layer 500 to the crystalline phase (e.g., to set the subsequently formed memory cell MC). Similarly, the bottom electrode 400 heats the variable resistance layer 500 to a second temperature that melts the variable resistance layer 500, so as to change the variable resistance layer 500 to the amorphous phase (e.g., to reset the subsequently formed memory cell MC). In some embodiments, the first temperature is lower than the second temperature. For example, the first temperature is about 100° C. to about 200° C. and the second temperature is about 500° C. to about 800° C. Since the phase change of the variable resistance layer 500 relies on the temperature difference, thermal confinement is crucial in the memory cell MC. As mentioned above, upon heating, the thermal preservation layer 300 has higher temperature than the bottom electrode 400 (i.e. the first electrode 402 and the second electrode 404). Since the thermal preservation layer 300 is closer to the variable resistance layer 500 than the first electrode 402, the thermal preservation layer 300 may effectively serve as an additional heat source (other than the first electrode 402 and the second electrode 404) to contribute to the phase change of the variable resistance layer 500. Moreover, since the thermal preservation layer 300 wraps around the second electrode 404 and is relatively close to the variable resistance layer 500, the thermal preservation layer 300 may also serve as a heat confinement layer which prevents heat from dissipating out of the second electrode 404. In other words, the thermal preservation layer 300 sufficiently aids the thermal confinement within the bottom electrode 400 and the variable resistance layer 500, thereby ensuring the performance of the subsequently formed memory cell MC.

In some embodiments, the amount of heat generated by the bottom electrode 400 varies in proportion to the current applied to the bottom electrode 400. That is, the variable resistance layer 500 is heated up to a certain temperature when a certain current passes through the bottom electrode 400. In other words, the reset current (I_{RESET}) of the subsequently formed memory cell MC is related to the heat conserved within the variable resistance layer 500. As mentioned above, since heat preservation layer 300 sufficiently aids the thermal confinement within the variable resistance layer 500, the configuration shown in FIG. 2G may also sufficiently lower the reset current of the subsequently formed memory cell MC. As such, the performance of the subsequently formed memory cell MC may be further enhanced.

Referring to FIG. 2H, a top electrode 600 is formed on the variable resistance layer 500. In some embodiments, a material of the top electrode 600 is the same as the material of the first electrode 402 and the second electrode 404. However, the disclosure is not limited thereto. In some alternative embodiments, the material of the top electrode 600 may be different from the material of the first electrode 402 and the second electrode 404. In some embodiments, the top electrode 600 includes a metallic material, such as Ti, Co, Cu, AlCu, W, TiN, TiW, TiAl, TiAlN, Ru, a combination thereof, or the like. In some alternative embodiments, the top electrode 600 includes a metal oxide material, such as TiOₓ, WOₓ, RuOₓ, a combination thereof, or the like. In some embodiments, the top electrode 600 is deposited through ALD, CVD, PVD, or the like.

Referring to FIG. 2I, a hard mask layer 700 is formed on the top electrode 600. In some embodiments, the hard mask layer 700 is made of non-metallic materials, such as SiO₂, SiC, SiN, SiON, or the like. However, the disclosure is not limited thereto. In some alternative embodiments, the hard mask layer 700 is made of metallic materials, such as Ti, TiN, Ta, TaN, Al, or the like. In some embodiments, the hard mask layer 700 is formed by CVD, PECVD, ALD, PVD, a combination thereof, or the like.

Referring to FIG. 2J, a photoresist layer PR1 is formed on the hard mask layer 700. In some embodiments, the photoresist layer PR1 partially coves the hard mask layer 700. In other words, at least a portion of the hard mask layer 700 is exposed by the photoresist layer PR1.

Referring to FIG. 2J and FIG. 2K, the hard mask layer 700, the top electrode 600, and the variable resistance layer 500 are patterned using the photoresist layer PR1 as a mask. For example, an etching process is performed to remove a portion of the hard mask layer 700, a portion of the top electrode 600, and a portion of the variable resistance layer 500 that are not covered by the photoresist layer PR1. The etching process includes, for example, an anisotropic etching process such as dry etch or an isotropic etching process such as wet etch. Subsequently, the photoresist layer PR1 is removed through a stripping process or the like. In some embodiments, the hard mask layer 700, the top electrode 600, and the variable resistance layer 500 are patterned simultaneously through the same process. As such, sidewalls of the hard mask layer 700, sidewalls of the top electrode 600, and sidewalls of the variable resistance layer 500 are aligned. As illustrated in FIG. 2K, after the hard mask layer 700, the top electrode 600, and the variable resistance layer 500 are patterned, a portion of the dielectric layer 200 is exposed.

Referring to FIG. 2L, a pair of spacers 800 is formed aside the hard mask layer 700, the top electrode 600, and the variable resistance layer 500. For example, the pair of spacers 800 is disposed on the dielectric layer 200 and covers the sidewalls of the hard mask layer 700, the sidewalls of the top electrode 600, and the sidewalls of the variable resistance layer 500. In some embodiments, the spacers 800 are formed of dielectric materials, such as silicon oxide, silicon nitride, SiCN, SiOCN, a combination thereof, or the like. In some embodiments, the spacers 800 are formed by a deposition followed by an anisotropic etch. Although FIG. 2L illustrated that the spacers 800 are single-layered structure, the disclosure is not limited thereto. In some alternative embodiments, the spacers 800 may be a multi-layered structure.

Referring to FIG. 2M, an etch stop layer 900 is formed on the dielectric layer 200, the pair of spacers 800, and the hard mask layer 700. For example, the etch stop layer 900 conformally covers the dielectric layer 200, the pair of spacers 800, and the hard mask layer 700. In some embodiments, the etch stop layer 900 includes silicon carbide, silicon nitride, silicon oxynitride, silicon carbo-nitride, or multi-layers thereof. In some embodiments, the etch stop layer 900 is deposited using CVD, HDP-CVD, SACVD, molecular layer deposition (MLD), or other suitable methods.

Referring to FIG. 2N, a dielectric layer 1000 is disposed on the etch stop layer 900. In some embodiments, a material of the dielectric layer 1000 is the same as the material of the dielectric layer 200. However, the disclosure is not limited thereto. In some alternative embodiments, the material of the dielectric layer 1000 is different from the material of the dielectric layer 200. In some embodiments, the dielectric layer 1000 is formed of a low-k dielectric material having a k-value lower than about 3.0, about 2.5, or even lower. In some alternative embodiments, the dielectric layer 1000 is formed of non-low-k dielectric materials such as silicon oxide, SiC, SiCN, SiOCN, or the like. In yet some alternative embodiments, the material of the dielectric layer 1000 includes polyimide, epoxy resin, acrylic resin, phenol resin, BCB, PBO, or any other suitable polymer-based dielectric material. The dielectric layer 1000 may be formed by suitable fabrication techniques such as spin-on coating, CVD, PECVD, or the like.

Referring to FIG. 2O, a hard mask layer 1100 is disposed on the dielectric layer 1000. In some embodiments, a material of the hard mask layer 1100 is the same as the material of the hard mask layer 700. However, the disclosure is not limited thereto. In some alternative embodiments, the material of the hard mask layer 1100 is different from the material of the hard mask layer 700. In some embodiments, the hard mask layer 1100 is made of non-metallic materials, such as SiO₂, SiC, SiN, SiON, or the like. However, the disclosure is not limited thereto. In some alternative embodiments, the hard mask layer 1100 is made of metallic materials, such as Ti, TiN, Ta, TaN, Al, or the like. In some embodiments, the hard mask layer 1100 is formed by CVD, PECVD, ALD, PVD, a combination thereof, or the like.

As illustrated in FIG. 2O, a photoresist layer PR2 is formed on the hard mask layer 1100. In some embodiments, the photoresist layer PR2 partially covers the hard mask layer 1100. For example, the photoresist layer PR2 has an opening OP3 which exposes a portion of the hard mask layer 1100.

Referring to FIG. 2O and FIG. 2P, the hard mask layer 1100, the dielectric layer 1000, the etch stop layer 900, the hard mask layer 700, and the top electrode 600 are patterned using the photoresist layer PR2 as a mask. For example, an etching process is performed to remove a portion of the hard mask layer 1100, a portion of the dielectric layer 1000, a portion of the etch stop layer 900, a portion of the hard mask layer 700, and a portion of the top electrode 600, so as to form an opening OP4. The etching process includes, for example, an anisotropic etching process such as dry etch or an isotropic etching process such as wet etch. Subsequently, the photoresist layer PR2 is removed through a stripping process or the like. As illustrated in FIG. 2P, the opening OP4 penetrates through the hard mask layer 1100, the dielectric layer 1000, the etch stop layer 900, and the hard mask layer 700. On the other hand, although the opening OP4 does not penetrate through the top electrode 600, the opening OP3 extends into the top electrode 600.

Referring to FIG. 2Q, a conductive contact 1200 is formed in the opening OP4 to form the memory cell MC. In some embodiments, the conductive contact 1200 is formed by filling a conductive material (not shown) into the opening OP4. The conductive material includes, for example, tungsten, aluminum, copper, titanium, tantalum, titanium nitride, tantalum nitride, alloys therefore, and/or multi-layers thereof. Subsequently, a planarization process is performed to remove excess portions of the conductive material over the hard mask layer 1100, so as to form the conductive contact 1200. As illustrated in FIG. 2Q, the conductive contact 1200 penetrates through the hard mask layer 1100, the dielectric layer 1000, the etch stop layer 900, and the hard mask layer 700 to be in physical contact with the top electrode 600. As mentioned above, since the opening OP4 extends into the top electrode 600, the conductive contact 1200, which fills up the opening OP4, also extends into the top electrode 600. For example, as illustrated in FIG. 2Q, a bottom surface B₁₂₀₀ of the conductive contact 1200 is located at a level height lower than that of a topmost surface T₆₀₀ of the top electrode 600.

Referring to FIG. 2Q and FIG. 1, some of the conductive vias 32 shown in FIG. 1 may serve as the conductive contact 1200 to electrically connect the memory cell MC with the conductive patterns 34. In other words, the memory cell MC is electrically connected to the first transistor T1, the second transistor T2, and/or the conductive terminals 70 through the conductive vias 32 and the conductive patterns 34 of the interconnection structure 30.

In accordance with some embodiments of the disclosure, a memory cell includes a bottom electrode, a thermal preservation layer, a first dielectric layer, a variable resistance layer, and a top electrode. The bottom electrode includes a first electrode and a second electrode spatially separated from the first electrode. The thermal preservation layer is partially sandwiched between the first electrode and the second electrode. The first dielectric layer laterally surrounds the bottom electrode and the thermal preservation layer. The variable resistance layer is disposed on the second electrode, the thermal preservation layer, and the first dielectric layer. The top electrode is disposed on the variable resistance layer.

In accordance with some embodiments of the disclosure, an integrated circuit includes a substrate, a transistor, and an interconnect structure. The transistor is over the substrate. The interconnect structure is disposed on the substrate. The interconnect structure includes a memory cell. The memory cell includes a bottom electrode, a thermal preservation layer, a variable resistance layer, and a top electrode. The bottom electrode includes a first electrode and a second electrode spatially separated from the first electrode. The thermal preservation layer covers a top surface of the first electrode, a bottom surface of the second electrode, and sidewalls of the second electrode. The variable resistance layer is disposed on the second electrode and the thermal preservation layer. The top electrode is disposed on the variable resistance layer.

In accordance with some embodiments of the disclosure, a manufacturing method of a memory cell includes at least the following steps. A dielectric layer having an opening is provided. A first electrode is formed to partially fill up the opening. A thermal preservation layer and a second electrode are sequentially formed on the first electrode to completely fill up the opening. The thermal preservation layer is partially sandwiched between the second electrode and the dielectric layer. A variable resistance layer is deposited on the dielectric layer, the thermal preservation layer, and the second electrode. A top electrode is formed on the variable resistance layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory cell, comprising:
a bottom electrode, comprising a first electrode and a second electrode spatially separated from the first electrode;
a thermal preservation layer partially sandwiched between the first electrode and the second electrode;
a first dielectric layer laterally surrounding the bottom electrode and the thermal preservation layer;
a variable resistance layer disposed on the second electrode, the thermal preservation layer, and the first dielectric layer; and
a top electrode disposed on the variable resistance layer.

2. The memory cell of claim 1, wherein the first electrode is in physical contact with the first dielectric layer.

3. The memory cell of claim 2, wherein the thermal preservation layer is partially sandwiched between the second electrode and the first dielectric layer.

4. The memory cell of claim 1, wherein a width of the first electrode is larger than a width of the second electrode.

5. The memory cell of claim 1, wherein the first electrode and the second electrode are made of a same material.

6. The memory cell of claim 1, wherein the bottom electrode and the thermal preservation layer are made of different materials.

7. The memory cell of claim 1, further comprising:
a hard mask layer disposed on the top electrode;
a pair of spacers disposed aside the variable resistance layer, the top electrode, and the hard mask layer;
an etch stop layer covering the first dielectric layer, the pair of spacers, and the hard mask layer;
a second dielectric layer disposed on the etch stop layer; and
a conductive contact penetrating through the second dielectric layer, the etch stop layer, and the hard mask layer to be in physical contact with the top electrode.

8. The memory cell of claim 7, wherein a bottom surface of the conductive contact is located at a level height lower than that of a topmost surface of the top electrode.

9. The memory cell of claim 7, wherein sidewalls of the hard mask layer, sidewalls of the top electrode, and sidewalls of the variable resistance layer are aligned.

10. An integrated circuit, comprising:
a substrate;
a transistor over the substrate; and
an interconnect structure disposed on the substrate, comprising;
a memory cell, comprising:
a bottom electrode, comprising a first electrode and a second electrode spatially separated from the first electrode;
a thermal preservation layer covering a top surface of the first electrode, a bottom surface of the second electrode, and sidewalls of the second electrode;
a variable resistance layer disposed on the second electrode and the thermal preservation layer; and
a top electrode disposed on the variable resistance layer.

11. The integrated circuit of claim 10, wherein sidewalls of the thermal preservation layer are aligned with sidewalls of the first electrode.

12. The integrated circuit of claim 11, wherein the memory cell further comprises a dielectric layer covering the sidewalls of the thermal preservation layer and the sidewalls of the first electrode.

13. The integrated circuit of claim 10, wherein the first electrode and the second electrode are made of a same material.

14. The integrated circuit of claim 10, wherein a width of the first electrode is larger than a width of the second electrode.

15. The integrated circuit of claim 10, wherein the variable resistance layer comprises an indium(In)-antimony(Sb)-tellurium (Te) (IST) material or a germanium(Ge)-antimony(Sb)-tellurium(Te) (GST) material.

16. A manufacturing method of a memory cell, comprising:
providing a dielectric layer having an opening;
forming a first electrode to partially fill up the opening;
sequentially forming a thermal preservation layer and a second electrode on the first electrode to completely fill up the opening, wherein the thermal preservation layer is partially sandwiched between the second electrode and the dielectric layer;
depositing a variable resistance layer on the dielectric layer, the thermal preservation layer, and the second electrode; and
forming a top electrode on the variable resistance layer.

17. The method of claim 16, wherein forming the first electrode comprises:
depositing a first electrode material layer in the opening of the dielectric layer to completely fill up the opening; and
removing a portion of the first electrode material layer to form the first electrode in the opening, wherein a top surface of the first electrode is located at a level height lower than that of a top surface of the dielectric layer.

18. The method of claim 16, wherein forming the thermal preservation layer and the second electrode comprises:
conformally forming a thermal preservation material layer on the dielectric layer and the first electrode, wherein the thermal preservation material layer extends into the opening of the dielectric layer to cover sidewalls of the opening and a top surface of the first electrode;
depositing a second electrode material layer on the thermal preservation material layer to completely fill up the opening; and
removing a portion of the thermal preservation material layer and a portion of the second electrode material layer until the dielectric layer is exposed, so as to form the thermal preservation layer and the second electrode in the opening.

19. The method of claim 16, further comprising:
forming a hard mask layer on the top electrode; and
patterning the hard mask layer, the top electrode, and the variable resistance layer to expose a portion of the dielectric layer.

20. The method of claim 19, wherein the hard mask layer, the top electrode, and the variable resistance layer are patterned simultaneously through a same process.
